(19) United States
(12) Patent Application Publication
(10) Pub. No.: US 2026/0033315 A1
(43) Pub. Date: Jan. 29, 2026

(54) Power Gating in Integrated Circuit

(71) Applicant: International Business Machines Corporation, Armonk, NY (US)

(72) Inventors: Sagarika Mukesh, Albany, NY (US); Ruilong Xie, Niskayuna, NY (US); Tao Li, Slingerlands, NY (US); Nicholas Anthony Lanzillo, Wynantskill, NY (US)

(21) Appl. No.: 18/785,287

(22) Filed: Jul. 26, 2024

(51) Int. Cl. H01L 23/528; H01L 23/522; H01L 27/092; H01L 29/06; H01L 29/423; H01L 29/775; H01L 29/786

(52) U.S. Cl. CPC H01L 23/5286; H01L 23/5226; H10D 84/85; H10D 30/43; H10D 30/6735; H10D 30/6757; H10D 62/121

(57) ABSTRACT

An integrated circuit includes a frontside structure which includes a plurality of power gating transistors and at least one metalization layer above the power gating transistors. The circuit includes a backside structure below the power gating transistors of the frontside structure. The backside structure includes at least one global power rail, one local power rail and one ground rail. The global power rail, the local power rail and the ground rail are spatially separated from each other and are not laterally aligned.

### BACKGROUND

The present disclosure relates generally to integrated circuit design, and more specifically to power gating in integrated circuits.

Power gating in circuits is a technique used to reduce static power consumption (e.g., leakage power) by selectively turning off power supply to blocks of a circuit when they are not in use. Power gating is important in integrated circuits (ICs), where leakage power can constitute a significant portion of total power consumption. The primary objective of power gating is to minimize leakage power by disconnecting the power supply to inactive circuit blocks. This technique extends battery life in portable devices and reduces power consumption in larger systems.

Power gating is implemented using power gating cells that may include transistors and control logic. These transistors are typically high-threshold voltage (high VT) PMOS and NMOS transistors. PMOS transistors are used to disconnect a supply voltage (VDD), and NMOS transistors are used to disconnect the ground (VSS).

When a circuit block is active, the transistors are turned on, providing a path for current from a power supply to the circuit block. This allows the circuit block to operate normally. When a circuit block is inactive, the transistors are turned off, disconnecting the power supply. This significantly reduces leakage current, as the isolated circuit block no longer draws power.

In power gating circuits, global VDD rails (e.g., global power supply) are used to provide power to all circuit blocks. One or more transistors may be used to route power from the global VDD rails to local VDD rails (e.g., local power grids) which selectively provide power to certain circuit blocks.

Implementing power gating in three-dimensional ICs presents challenges as transistor sizes shrink and the number of transistors in ICs increases. Three-dimensional ICs (e.g., nanosheet-based ICs and FinFet-based ICs) involve complex interconnect networks between different layers. In three-dimensional ICs, power gating requires additional interconnects for control signals and power delivery between different layers, complicating the already intricate routing and potentially increasing parasitic capacitances and resistances.

Existing IC designs have drawbacks because local VDD rails (local power grids), global VDD rails (global power supply) and VSS rails (ground rails) are vertically stacked directly above or below each other on a single plane or they are laterally aligned on the same line. Aligning local and global VDD rails and VSS rails occupies significant silicon area that can otherwise be used for additional transistors. This alignment reduces the available space for active devices (e.g., transistors), limiting the overall transistor density.

### SUMMARY

An integrated circuit comprises a frontside structure which includes a plurality of power gating transistors and at least one metalization layer above the power gating transistors. The metalization layer is electrically connected to the power gating transistors. The integrated circuit comprises a backside structure below the power gating transistors. The backside structure includes at least one global power rail, one local power rail, and one ground rail. The global power rail, the local power rail, and the ground rail are spatially separated from each other and are positioned at different lateral levels. The global power rail, the local power rail, and the ground rail are not vertically stacked directly above or below each other and are not laterally aligned. The frontside structure includes a middle of line connector layer configured to electrically connect the power gating transistors to upper interconnect layers. The backside structure includes at least one backside connector configured to connect a first subset of the power gating transistors to the global power rail. The backside structure includes at least one backside connector configured to connect a second subset of the power gating transistors to the local power rail. The backside structure includes an inter-layer dielectric configured to isolate metal interconnect layers.

### BRIEF DESCRIPTION OF THE DRAWINGS

The novel features believed characteristic of the illustrative embodiments are set forth in the appended claims. The illustrative embodiments, however, as well as a preferred mode of use, further objectives and features thereof, will best be understood by reference to the following detailed description of an illustrative embodiment of the present disclosure when read in conjunction with the accompanying drawings, wherein:

FIG. 1 illustrates a top view of an integrated circuit (IC) in accordance with an illustrative embodiment;

FIGS. 2, 3 and 4 are cross-sectional views of an IC in accordance with an illustrative embodiment; and

FIG. 5 illustrates a three-dimensional view of an IC in accordance with an illustrative embodiment.

### DETAILED DESCRIPTION

The illustrative embodiments address limitations of existing techniques for implementing power gating in integrated circuits (ICs).

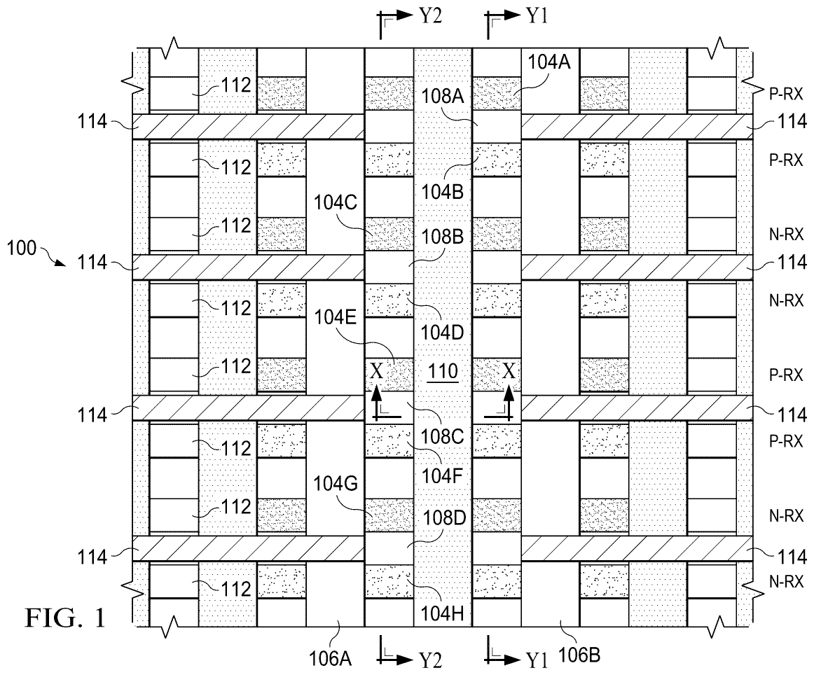

With reference to FIG. 1, a top view of IC 100 is depicted in accordance with an illustrative embodiment. IC 100 is fabricated on a semiconductor wafer. In this view, a plurality of silicon (Si) channels 104A-104H of power gating transistors are shown. Channels 104A-104H are regions where current flows between a source terminal and a drain terminal (not shown in FIG. 1). Channels 104A-104H are formed between single layer diffusion breaks (SDBs) 106A and 106B which are dielectric trenches separating functional areas of IC 100. The power gating transistors have gate 110 formed over the channels. Metalization layers 108A-108D are formed below channels 104A-104H of the power gating transistors. The metalization layers can, for example, be power rails or grids (e.g., local power rails or global power rails).

IC 100 includes a plurality of logic transistors 112 in a logic region of IC. Logic transistors 112 can be NMOS transistors and/or PMOS transistors which are separated from the power gating transistors by SDBs 106A and 106B. In this view, trenches 114 are shown to define isolation regions to separate adjacent transistors. One or more logic transistors (e.g., transistors 112) form circuit blocks (not shown in FIG. 1) in the logic region. These circuit blocks are electrically connected to the local power rails. These circuit blocks are also electrically connected to the global power rails via the local power rails and the power gating transistors.

By turning OFF one or more power gating transistors, these circuit blocks can be selectively electrically disconnected from the global power rails when they are not in use. When one or more power gating transistors are turned OFF, selected local power rails are electrically disconnected from the global power rails. The effect of this is that one of circuit blocks (not shown in FIG. 1) not in use are electrically disconnected from the global power rails, thus reducing leakage current and power consumption.

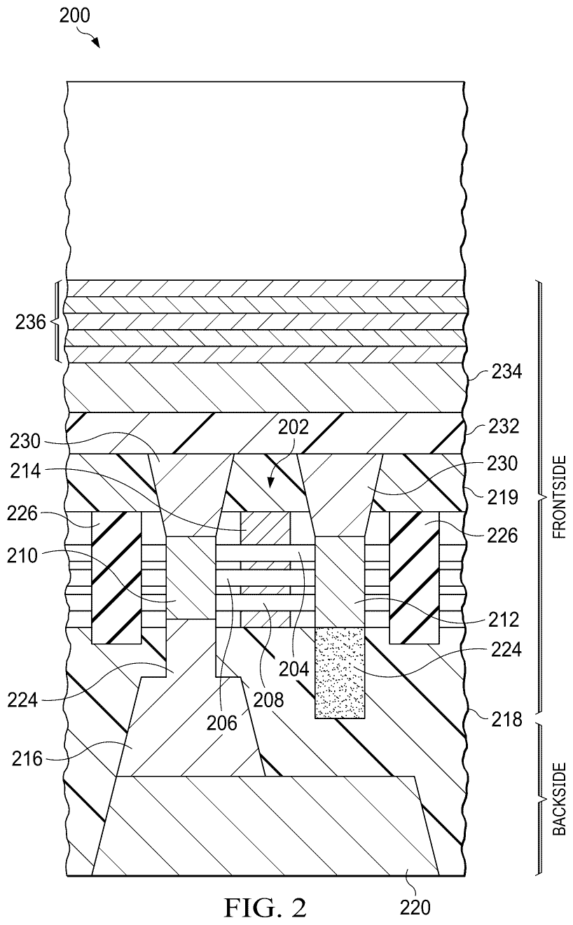

IC 100 can be cut along lines X, Y1 and Y2 to illustrate different cross-sectional views which are described with references to FIGS. 2-5. The operation of the power gating transistors are described with references to FIGS. 2-5.

FIG. 2 is cross-sectional view 200 of a plane cut along line X of IC 100 in FIG. 1. In cross-sectional view 200, a single power gating transistor is shown.

Power gating transistor 202 includes silicon (Si) channels 204, 206 and 208. Channels 204, 206 and 208 are regions in transistor 202 where current flows between source/drain (S/D) regions 210 and 212. If S/D region 210 is a source, then S/D region 212 is a drain, and vice versa. For an NMOS transistor, the source and drain regions are heavily doped with n-type dopants, such as phosphorus or arsenic. For a PMOS transistor, the source and drain regions are heavily doped with p-type dopants, such as boron. Although only three channels are shown, transistor 202 can be fabricated having more or fewer channels.

Transistor 202 includes gate 214 formed above channels 204, 206 and 208. Gate 214 is separated from the channels by a thin insulating layer (gate dielectric) made of, for example, silicon dioxide (SiO₂) or hafnium oxide (HfO₂). A thin layer of SiO₂ is grown on the surface of the silicon wafer. A layer of polysilicon or metal is deposited on top of the oxide layer and patterned to form gate 214.

When a voltage is applied to gate 214, it creates an electric field that modulates the conductivity of channels 204, 206 and 208. In NMOS transistors, when the applied voltage (gate-to-source voltage VGS) exceeds a threshold voltage (VT), a conduction path exists between the drain and the source, causing current to flow from the source to the drain through the channels. In PMOS transistors, when the applied voltage (VGS) is below the threshold voltage (VT), a conduction path exists between the source and the drain, causing current to flow from the source to the drain through the channels.

The IC includes back side metal contact (BSCA) 216 (metalization layer) which connects source region 210 to local VDD rail 220. Local VDD rail 220 is a local power grid which selectively provides power to selected circuit blocks (not shown in FIG. 2) in the IC. When transistor 202 is turned ON, power from local VDD rail is distributed to selected circuit blocks. BSCA 216 is formed by depositing a metal layer on the backside (non-active side) of the semiconductor wafer to provide electrical contact between local VDD rail 220 and transistor 202. BSCA 216 provides a low resistance path for current to flow from transistor 202 to other circuit blocks in the IC. Inter layer dielectric (ILD) 218 is deposited in the backside region between local VDD rail 220 and the transistor. ILD 218 is formed using an insulating material (e.g., silicon dioxide) to isolate different metal interconnect layers, preventing short circuits and crosstalk between signals.

S/D regions 210 and 212 are fabricated over place holders 224. Place holders 224 are used to define the specific areas on the semiconductor wafer where the source and drain regions are formed. This ensures proper alignment of BSCA 216 with the source and drain regions.

The IC includes single diffusion blocks (SDBs) 226 which physically separate active areas. SDB 226 is a trench or gap introduced between diffusion regions of adjacent transistors or cells. SDB 226 electrically isolates diffusion regions of adjacent transistors, preventing unwanted electrical conduction and leakage. SDB 226 can be formed by filling the trench with a dielectric material (e.g., silicon oxide or silicon nitride).

The IC includes middle of line layer 230 which connects transistor 202 to upper interconnect layers of the IC. Middle of line layer 230 acts as a source electrode or a drain electrode. Middle of line layer 230 facilitates signal routing. Middle of line layer 230 is a metalization layer that connects the active regions of the transistor (source, drain) to the upper interconnect layers. This layer bridges the gap between the front-end-of-line (FEOL) area, where transistors and other active devices are fabricated, and the back-end-of-line (BEOL) area, where interconnects are formed.

After the middle of line process, dielectric layer 232 (e.g., silicon dioxide) is deposited over the wafer. Dielectric layer 232 is an interlayer dielectric through which vertical interconnects (vias) can be formed to electrically connect the transistor to upper metalization layers. Metal layers are patterned over dielectric layer 232.

The IC includes metal level one (M1) 234 (metalization layer) which is the first layer of metal interconnect in the back-end-of-line (BEOL) process in IC 100 fabrication. M1 234 connects various components of the IC, such as transistors, to each other and to higher levels of the metal interconnect stack. M1 234 connects the transistor's source, drain and gate to higher metal layers.

The IC may have higher metal layers (e.g., M2, M3, M4) in BEOL stack 236. Higher metal layers are built upon M1 234 to create a complete network of interconnections required for the IC's operation. M1 234 is connected to higher metal layers through vertical interconnects (vias).

In FIG. 2, the region or layers below the transistor is referred to as the backside structure, and the region or layers above the backside structure is referred to as the frontside structure.

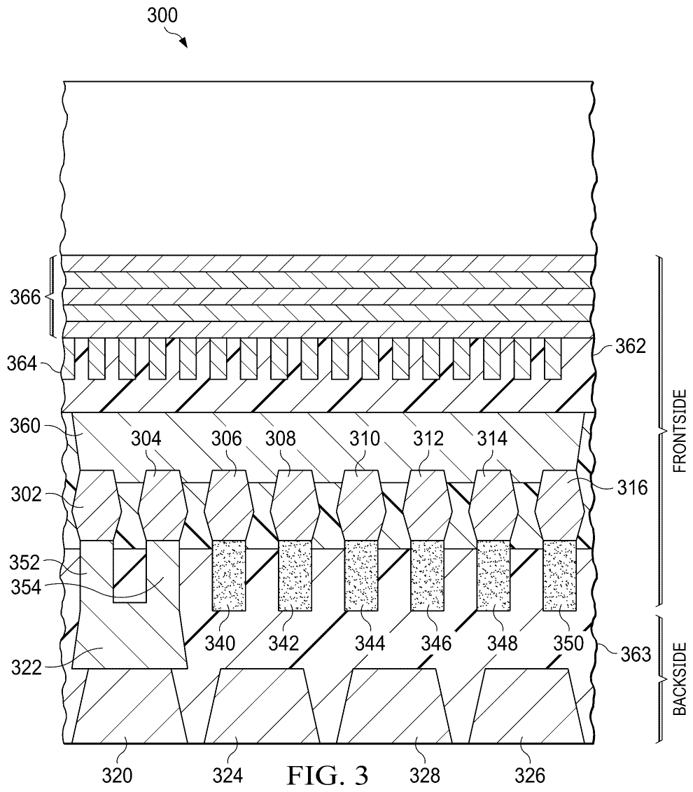

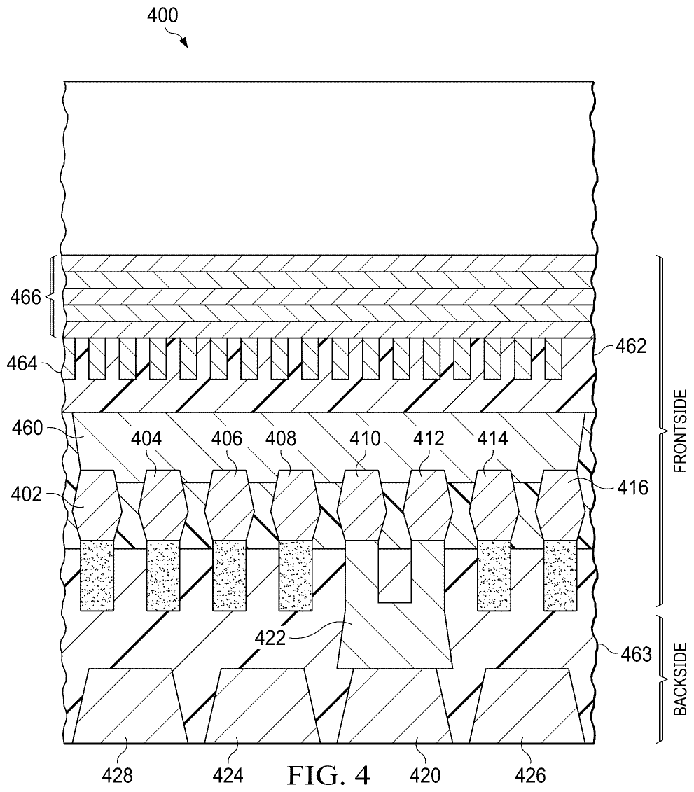

In the illustrative embodiment, local VDD rail 220 is fabricated in the backside structure. Also, as shown in FIGS. 3 and 4, global VDD rails, local VDD rails and VSS rails are fabricated in the backside structure. An advantage of fabricating the power rails and ground rails in the backside structure is that it reduces conductor crowding in the frontside. As a result, more frontside area is available for transistors and signal routing.

In an example embodiment, one or more circuit blocks (not shown in FIG. 2) are electrically connected to local VDD rail 220. Local VDD rail 220 is also connected to a global VDD rail (not shown in FIG. 2) via power gating transistor 202. When the circuit blocks (not shown in FIG. 2) connected to local VDD rail 220 are inactive, power gating transistor 220 can be turned OFF to disconnect local VDD rail 220 from the global VDD rail (not shown in FIG. 2). As a result, one or more circuit blocks connected to the local VDD rail are electrically disconnected from the global VDD rail, thus reducing leakage current and power consumption.

FIG. 3 is cross-sectional view 300 of a plane cut along line Y1 of IC 100 in FIG. 1. In cross-sectional view 300, a plurality of power gating transistors is shown.

The IC includes power gating transistors 302, 304, 306, 308, 310, 312, 314 and 316 fabricated in a semiconductor wafer. In this illustrative embodiment, only power gating transistors 302 and 304 are connected to local VDD rail 320 via BSCA 322. BSCA 322 is formed by depositing a metal layer on the backside (non-active side) of the semiconductor wafer to provide electrical contact. BSCA 322 provides a low resistance path for current to flow from transistors 302 and 304 to other circuit blocks in the IC. BSCA 322 is connected to only a subset of the power gating transistors (e.g., transistors 302 and 304) in the IC.

One or more circuit blocks (not shown in FIG. 3) are electrically connected to local VDD rail 320. When power gating transistors 302 and 304 are turned ON, power is distributed from global VDD rail 328 to local VDD rail 320, and when power gating transistors 302 and 304 are turned OFF, local VDD rail 320 is disconnected from global VDD rail 328. Thus, by turning ON/OFF power gating transistors, one or more circuit blocks (not shown in FIG. 3) can be connected/disconnected from global VDD rail 328. When selected circuit blocks are not in use, power supply to those circuit blocks can be cut off by turning off power gating transistors 302 and 304, thus reducing leakage current and power consumption.

As discussed before, existing power gating designs have drawbacks because the VSS rails, local VDD rails and global VDD rails are vertically stacked directly above or below each other, or they are laterally aligned. Aligning local and global VDD rails and VSS rails laterally occupies significant silicon area that can otherwise be used for additional transistors. This alignment reduces the available space for active devices, limiting the overall transistor density.

The illustrative embodiments address the limitations of existing power gating designs. In the illustrative embodiment, VSS rails 324 and 326 (e.g., ground) and global VDD rail 328 (e.g., global supply voltage) are spatially separated from each other and are not laterally aligned. Local VDD rail 320, VSS rails 324 and 326 and global VDD rail 328 are not vertically stacked directly above or below each other. As a result, more area is available space for active devices. In some example embodiments, the power and ground rails can be positioned in different planes or levels within the IC.

In the illustrative embodiment, VSS rails 324 and 326 provide a reference voltage (e.g., ground) throughout the IC. Global VDD rail 328 distributes supply voltage throughout the IC. Global VDD rail 328 ensures all parts of the IC receive a stable voltage supply. Global VDD rail 328 can be connected to an external power pad.

The IC includes a plurality of place holders 340, 342, 344, 346, 348, 350, 352 and 354. Place holders are used to define the specific areas on the semiconductor wafer where the source and drain regions are formed.

The IC includes middle of line layer 360 which connects the transistors to upper interconnect layers. In the illustrative embodiments, middle of line layer 360 is a continuous layer which is connected to transistors 302, 304, 306, 308, 312, 314 and 316 which are formed between two single diffusion blocks (not shown in FIG. 3). Thus, in contrast to BSCA 322 which is connected to only a subset of the transistors, middle of line layer 360 is connected to all transistors between two single diffusion blocks (not shown in FIG. 3). Middle of line layer 360 is formed by depositing metal in the frontside region between the active elements and upper interconnect layers. Middle of line layer 360 facilitates signal routing and power distribution.

After the middle of line process, frontside ILD 362 (e.g., silicon dioxide) is deposited over the wafer. Vias may be formed through ILD 362 to connect the transistors to higher metalization layers. Backside ILD 363 is deposited in the backside region using an insulating material (e.g., silicon dioxide) to isolate different metal interconnect layers, preventing short circuits and crosstalk between signals.

The IC includes metal level one (M1) 364 which is the first layer of metal interconnect in the back-end-of-line (BEOL) process. M1 364 connects various components of the IC, such as transistors, to each other and to higher levels of the metal interconnect stack. M1 364 can serve as a signal rail.

The IC may include higher metal layers (e.g., M2, M3, M4) in BEOL stack 366. Higher metal layers are built upon M1 364 to create the complete network of interconnections required for IC 100′s operation.

In FIG. 3, the region or layers below the transistors are referred to as the backside structure, and the region or layers above the backside structure is referred to as the frontside structure. In the illustrative embodiment, local VDD rail 320, VSS rails 324 and 328 and global VDD rail 328 are formed in the backside structure. An advantage of fabricating the power rails and ground rails in the backside structure is that it reduces conductor crowding in the frontside. As a result, more area in the frontside is available for transistors and signal routing.

Although in this illustrative embodiment, local VDD rail 320, VSS rails 324 and 328 and global VDD rail 328 are formed on a same plane in the backside structure, in other embodiments they can be formed in different levels in the backside structure.

FIG. 4 is cross-sectional view 400 of a plane cut along line Y2 of IC 100 in FIG. 1. In cross-sectional view 400, a plurality of power gating transistors is shown.

As illustrated in FIG. 4, the IC includes power gating transistors 402, 404, 406, 408, 410, 412, 414 and 416. In this illustrative embodiment, power gating transistors 410 and 412 are connected to global VDD rail 420 via BSCA 422. BSCA 422 is connected to only a subset of the power gating transistors (e.g., transistors 410 and 412) in the IC.

The IC includes VSS rails 424 and 426 and local VDD rail 428 which are spatially separated. Local VDD rail 428, VSS rails 424 and 426 and global VDD rail 420 are not vertically stacked directly above or below each other. Also, local VDD rail 428, VSS rails 424 and 426 and global VDD rail 420 are not laterally aligned.

By placing the local VDD rail, global VDD rail and VSS rails spatially apart and not laterally aligned, more area is made available for placing transistors. This allows for more efficient use of the available silicon area, leading to higher transistor density.

The IC includes middle of line layer 460 which connects transistors 402, 404, 406, 408, 410 and 412 to upper interconnect layers. In the illustrative embodiments, middle of line layer 460 is a continuous layer which is connected to the transistors. Middle of line layer 460 facilitates signal routing and power distribution.

The ICC includes frontside ILD 462 (e.g., silicon dioxide) deposited over the wafer. Vias can be formed through frontside ILD 462 for interconnection between upper metalization layers and the transistors. Backside ILD 463 is deposited in the backside region to isolate different metal interconnect layers, preventing short circuits and crosstalk between signals.

The IC includes metal level one (M1) 464 which is the first layer of metal interconnect in the back-end-of-line (BEOL) process. M1 464 connects various components of the IC, such as transistors, to each other and to higher levels of the metal interconnect stack. M1 464 can serve as a signal rail.

The IC may include higher metal layers (e.g., M2, M3, M4) in BEOL stack 466. Higher metal layers are built upon M1 464 to create the complete network of interconnections required for IC 100's operation.

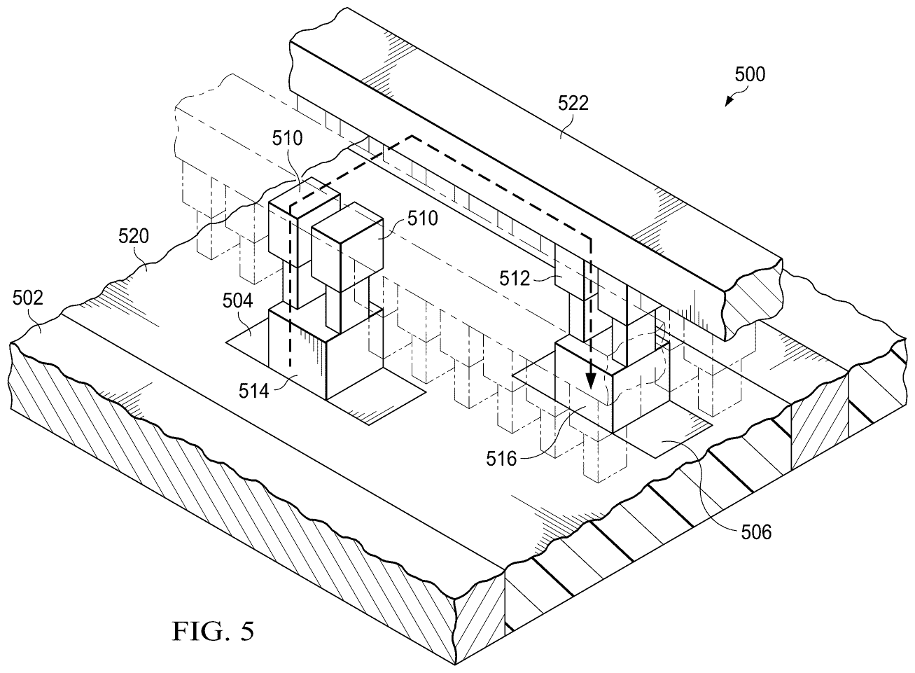

FIG. 5 illustrates a three-dimensional view of IC 500. IC 500 includes VSS rail 502, global VDD rail 504 and local VDD rail 506 which are spatially separated and not laterally aligned. VSS rail 502, global VDD rail 504 and local VDD rail 506 are not vertically stacked directly above or below each other. Also, VSS rail 502, global VDD rail 504 and local VDD rail 506 are formed in the backside structure of IC 500. As a result, more area in the frontside is available for transistors and signal routing.

In this illustrative embodiment, IC 500 includes power gating transistors 510 and 512. Transistor 510 is connected to global VDD rail 504 via BSCA 514, and transistor 512 is connected to local VDD rail 506 via BSCA 516. One or more circuit blocks (not shown in FIG. 5) are electrically connected to local VDD rail 506. When these circuit blocks (not shown in FIG. 5) are inactive, power gating transistor 512 can be turned OFF to disconnect local VDD rail 506 from global VDD rail 504. As a result, the circuit blocks (not shown in FIG. 5) which are connected to local VDD rail 506 are disconnected from global VDD rail 504, thus reducing leakage current and power consumption.

IC 100 includes middle of line layer 522 which connects the transistors to upper interconnect layers. In the illustrative embodiment, middle of line layer 522 is a continuous layer which connects the sources and drains (not shown in FIG. 5) of the transistors. As shown by arrows, power is routed from global VDD rail 504 to local VDD rail 506 via transistors 510 and 512. Inter layer dielectric (ILD) 520 is deposited in the backside region between the global VDD rail and the local VDD rail.

In an example embodiment, the IC can be fabricated on a semiconductor wafer. Multiple power gating transistors are formed on the wafer. The power gating transistors are bounded by single diffusion blocks (SDBs) to electrically isolate the transistors from normal logic regions of the IC. A middle of line contact layer (CA) is formed over the transistors on the frontside of the IC. The middle of line contact layer is electrically connected to multiple transistors. An interlayer dielectric (ILD) is formed over the middle of line contact layer, and a frontside interconnect (e.g., M1 contact layer) is formed over the ILD. This is followed by completion of the interconnect formation up until metal levels. The wafer is then bonded to a carrier wafer and flipped and the substrate is removed from the backside of the IC. A first backside contact and a second backside contact are formed. The first backside contact is connected to a first subset of the transistors and the second backside contact is connected to a second subset of the transistors. Next, a local VDD rail, a global VDD rail, and a VSS rail are formed in the backside. The local VDD rail is connected to the first backside contact, and the global VDD rail is connected to the second backside contact. As a result, the first subset of transistors are electrically connected to the local VDD rail and a second subset of the transistors are electrically connected to the global VDD rail.

As used herein, “a number of,” when used with reference to items, means one or more items. For example, “a number of different types of networks” is one or more different types of networks.

Further, the phrase “at least one of,” when used with a list of items, means different combinations of one or more of the listed items can be used, and only one of each item in the list may be needed. In other words, “at least one of” means any combination of items and number of items may be used from the list, but not all of the items in the list are required. The item can be a particular object, a thing, or a category.

For example, without limitation, “at least one of item A, item B, or item C” may include item A, item A and item B, or item B. This example also may include item A, item B, and item C or item B and item C. Of course, any combinations of these items can be present. In some illustrative examples, “at least one of” can be, for example, without limitation, two of item A; one of item B; and ten of item C; four of item B and seven of item C; or other suitable combinations.

The flowcharts and block diagrams in the different depicted embodiments illustrate the architecture, functionality, and operation of some possible implementations of apparatuses and methods in an illustrative embodiment. In this regard, each block in the flowcharts or block diagrams can represent at least one of a module, a segment, a function, or a portion of an operation or step. For example, one or more of the blocks can be implemented as program code, hardware, or a combination of the program code and hardware. When implemented in hardware, the hardware may, for example, take the form of integrated circuits that are manufactured or configured to perform one or more operations in the flowcharts or block diagrams. When implemented as a combination of program code and hardware, the implementation may take the form of firmware. Each block in the flowcharts or the block diagrams may be implemented using special purpose hardware systems that perform the different operations or combinations of special purpose hardware and program code run by the special purpose hardware.

In some alternative implementations of an illustrative embodiment, the function or functions noted in the blocks may occur out of the order noted in the figures. For example, in some cases, two blocks shown in succession may be performed substantially concurrently, or the blocks may sometimes be performed in the reverse order, depending upon the functionality involved. Also, other blocks may be added in addition to the illustrated blocks in a flowchart or block diagram.

The different illustrative examples describe components that perform actions or operations. In an illustrative embodiment, a component may be configured to perform the action or operation described. For example, the component may have a configuration or design for a structure that provides the component an ability to perform the action or operation that is described in the illustrative examples as being performed by the component.

Many modifications and variations will be apparent to those of ordinary skill in the art. Further, different illustrative embodiments may provide different features as compared to other illustrative embodiments. The embodiment or embodiments selected are chosen and described in order to best explain the principles of the embodiments, the practical application, and to enable others of ordinary skill in the art to understand the disclosure for various embodiments with various modifications as are suited to the particular use contemplated.

What is claimed is:

1. An integrated circuit, comprising:
a frontside structure comprising:
a plurality of power gating transistors;
at least one metalization layer above the power gating transistors and electrically connected to the power gating transistors; and
a backside structure below the power gating transistors, the backside structure comprising:
at least one global power rail, one local power rail, and one ground rail, wherein the global power rail, the local power rail, and the ground rail are spatially separated from each other and are positioned at different lateral levels.

2. The integrated circuit of claim 1, wherein the global power rail, the local power rail, and the ground rail are not vertically stacked directly above or below each other and are not laterally aligned.

3. The integrated circuit of claim 1, wherein the global power rail, the local power rail, and the ground rail are vertically separated from each other across different layers of the backside structure.

4. The integrated circuit of claim 1, wherein the frontside structure includes a middle of line connector layer configured to electrically connect the power gating transistors to upper interconnect layers.

5. The integrated circuit of claim 1, wherein the backside structure includes at least one backside connector configured to connect a subset of the power gating transistors to the global power rail.

6. The integrated circuit of claim 1, wherein the backside structure includes at least one backside connector configured to connect a subset of the power gating transistors to the local power rail.

7. The integrated circuit of claim 1, wherein the backside structure includes an inter-layer dielectric configured to isolate metal interconnect layers.

8. The integrated circuit of claim 1, wherein the power gating transistors include at least one PMOS transistor.

9. The integrated circuit of claim 1, wherein the power gating transistors include at least one NMOS transistor.

10. An integrated circuit, comprising:
a frontside structure comprising:
a plurality of power gating transistors;
a middle of line connector layer electrically connected to the power gating transistors; and
a backside structure below the power gating transistors, the backside structure comprising:
at least one global power rail, one local power rail, and one ground rail;
a first backside connector configured to electrically connect a first subset of the power gating transistors to the global power rail; and
a second backside connector configured to electrically connect a second subset of the power gating transistors to the local power rail, wherein the global power rail, the local power rail, and the ground rail are spatially separated from each other and are positioned at different lateral levels.

11. The integrated circuit of claim 10, wherein the local power rail, the global power rail, and the ground rail are separated from each other across different layers of the backside structure.

12. The integrated circuit of claim 10, wherein the middle of line connector layer connects the power gating transistors to upper interconnect layers.

13. The integrated circuit of claim 10, wherein the backside structure includes an inter-layer dielectric configured to isolate metal interconnect layers.

14. An integrated circuit, comprising:
a frontside structure comprising a plurality of power gating transistors;
a backside structure below the power gating transistors, the backside structure comprising:
at least one global power rail, one local power rail and one ground rail; and
a backside connector configured to electrically connect a subset of the power gating transistors to one of the global power rail or the local power rail, wherein the global power rail, the local power rail, and the ground rail are spatially separated from each other and are positioned at different lateral levels.

15. The integrated circuit of claim 14, wherein the local power rail, the global power rail, and the ground rail are spatially separated from each other across different layers of the backside structure.

16. The integrated circuit of claim 14, wherein the frontside structure includes a middle of line connector layer above the power gating transistors, wherein the middle of line connector is configured to connect the transistors to upper interconnect layers.

17. The integrated circuit of claim 14, wherein the backside structure includes an inter-layer dielectric configured to isolate metal interconnect layers.

18. The integrated circuit of claim 14, wherein the global power rail is configured to distribute a supply voltage throughout the integrated circuit.

19. The integrated circuit of claim 14, wherein the local power rails are configured to distribute power to selected circuit blocks.

20. The integrated circuit of claim 14, wherein the power gating transistors include at least one NMOS transistor and one PMOS transistor.
